(19) United States
(12) Patent Application Publication
(10) Pub. No.: US 2015/0303093 A1
(43) Pub. Date: Oct. 22, 2015

(54) Adhesive Sheet

(71) Applicant: LINTEC CORPORATION, Tokyo (JP)

(72) Inventor: Hironobu Fujimoto, Tokyo (JP)

(21) Appl. No.: 14/440,674

(22) PCT Filed: Nov. 1, 2013
(86) PCT No.: PCT/JP2013/079768

§ 371 Date: May 5, 2015

(30) Foreign Application Priority Data
Nov. 5, 2012 (JP) 2012-243785

(51) Int. Cl. H01L 21/683; C09J 7/02; B32B 27/32; B32B 27/06; B32B 7/12

(52) U.S. Cl. CPC H01L 21/6836; B32B 27/06; B32B 7/12; B32B 27/32; C09J 7/0296; B32B 2255/10; B32B 2457/14; B32B 2307/54; B32B 2305/72; B32B 2255/26; C09J 201/00

(57) ABSTRACT

An adhesive sheet includes a substrate film and an adhesive layer which is provided on the substrate film, wherein the substrate film is composed of an energy ray curable composition being formed into a film and cured, the composition including an energy ray curable resin and an ion liquid having ethylenically unsaturated bonds.

### TECHNICAL FIELD

The present invention relates to an adhesive sheet, and further specifically, the present invention relates to the adhesive sheet suitably used the temporal surface protection of the workpiece such as the semiconductor wafer or so and to fix and maintain the workpiece during the processing such as polishing and dicing.

### DESCRIPTION OF THE RELATED ART

As the recent semiconductor device becoming more compact and more high functional, the wiring pitch of the logic device has become narrower such as to several tens nm; thus the insulating film between the wires has also become thin and the risk of breaking the device due to the leakage current has increased. Therefore, there is also a demand of having an antistatic property to the adhesive sheet as well.

Conventionally, in general, as the method for providing the antistatic property to the adhesive sheet, the adhesive layer is provided on one face of the plastic base film of which is added with the antistatic agent therein, or the adhesive layer added with the antistatic agent, or the method of providing the antistatic layer are considered.

As the adhesive sheet provided with such antistatic property, the patent document 1 discloses the adhesive sheet wherein the antistatic agent is added to the adhesive layer, and providing the antistatic layer between the base film and the adhesive layer to give the antistatic property to the adhesive sheet for the semiconductor wafer fixing. Also, the patent document 2 discloses the adhesive sheet wherein the adhesive layer is provided on the base film comprising an urethane based oligomer and an energy ray polymerizable monomer and a metal salt antistatic agent such as lithium (Li) salt based; and the patent document 3 discloses, as the cover sheet for the transportation of the electronic member, the resin sheet comprising the ionic liquid.

However, the adhesive sheet or the resin sheet described in the patent documents 1 to 3 adds the antistatic agent to the adhesive layer or to the base film, thus as the use for the processing of the semiconductor wherein the adhesive sheet is being exposed to large amount of water or being heated, the antistatic agent may elute out during the processing; hence the predetermined antistatic property may not be able to obtain, or the eluted product may adhere to the semiconductor device, which may cause the performance of the device to decline.

Also, in general, the adhesive sheet is transported while being in contact with the metal guide roll or the table of the device for processing the semiconductor, in the semiconductor processing device such as the tape laminator or the mounter or so. However, in the resin sheet described in the patent document 3, the ionic liquid may segregate to the sheet surface, or may bleed out, thereby the static friction coefficient of the resin sheet surface may increase, and if the resin sheet is used as the semiconductor processing adhesive sheet, the resin sheet adheres to the stainless roll or to the table of the device for the semiconductor processing in the semiconductor processing device. Thereby, the sheet may wind around the roll, or may be adhered to the table and it may be not possible to take out from the device, and there is also a risk that the malfunction may occur during the semiconductor processing steps.

### PRIOR ART DOCUMENT

### Patent document

Patent document 1:JP Patent Application Laid Open No.2009-260332

Patent document 2:JP Patent Application Laid Open No.2010-177542

Patent document 3:JP Patent Application Laid Open No.2006-299120

### Means for Solving the Problems

The present invention is attained in view of such circumstances, and the object is to provide the adhesive sheet comprising the antistatic property, with low static friction coefficient at the sheet surface due to the bleed out of the antistatic agent, and with high semiconductor processing aptitude.

The present invention includes the following gist.

[1] An adhesive sheet comprising a base film and an adhesive layer provided on said base film, wherein

said base film is made by curing a membrane comprising an energy ray curable composition including an energy ray curable resin and an ionic liquid having the ethylenic unsaturated bonds.

[2] The adhesive sheet as set forth in [1], wherein said energy ray curable resin comprises a polymer or an oligomer having the ethylenic unsaturated bonds.

[3] The adhesive sheet as set forth in [1] or [2], wherein said energy ray curable resin includes an energy ray polymerizable monomer.

[4] The adhesive sheet as set forth in any one of [1] to [3], wherein said ionic liquid is a compound comprising polyoxyalkylene chain.

[5] The adhesive sheet as set forth in any one of [1] to [4], wherein said adhesive layer is an energy ray curing adhesive layer.

[6] The adhesive sheet as set forth in [2], wherein said polymer or oligomer comprising said ethylenic unsaturated bonds is an urethane based polymer or oligomer comprising the ethylenic unsaturated bonds.

[7] The adhesive sheet as set forth in any one of [1] to [6], wherein a face of said base film opposite to a face where the adhesive layer is provided has a static friction coefficient against a stainless board of 1.0 or less.

[8] The adhesive sheet as set forth in any one of [1] to [7], wherein a tensile modulus of said base film is 50 to 800 MPa.

[9] The adhesive sheet as set forth in any one of [1] to [8], wherein a breaking elongation of said base film is 80% or more.

[10] The adhesive sheet as set forth in any one of [1] to [9], wherein said adhesive layer is adhered to a circuit face for protecting said circuit face of a semiconductor wafer during a grinding step of a backside of the semiconductor wafer.

[11] The adhesive sheet as set forth in any one of [1] to [9], wherein said adhesive layer is adhered to a semiconductor wafer during a dicing step of the semiconductor wafer.

### The Effect of the Invention

According to the present invention, a predetermined antistatic property can be obtained stably, and the performance of the device does not decline. Also, the antistatic agent does not segregate at the surface of the base film, and the bleed out or so does not occur, thus the static friction coefficient of the surface of the base film is low, and the adhesive sheet having high processing aptitude during the semiconductor processing step can be obtained.

### BRIEF DESCRIPTION OF THE DRAWINGS

FIG. 1 is the cross section of the adhesive sheet according to one embodiment of the present invention.

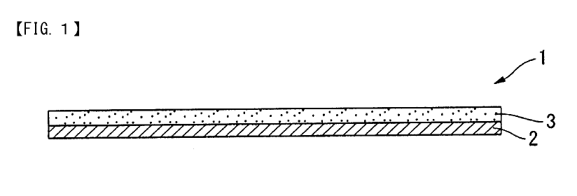

Hereinafter, the embodiment according to the present invention will be described based on the attached figure.

The adhesive sheet 1 according to the present invention is the adhesive sheet comprising the base film 2, and the adhesive layer 3 provided on said base film, wherein said base film is made by curing the membrane comprising an energy ray curable resin, and an ionic liquid comprising the ethylenic unsaturated bonds.

### [Base Film]

The base film is made by curing the membrane comprising the energy ray curable composition comprising the energy ray curable resin and the ionic liquid comprising the ethylenic unsaturated bonds.

### (Energy Ray Curable Resin)

The energy ray curable resin has the property of curing by receiving the energy ray irradiation. Therefore, by carrying out the energy ray irradiation after forming the membrane from the energy ray curable resin having appropriate viscosity, it cures and forms the film thereby the base film is obtained.

The energy ray curable resin preferably includes the polymer or the oligomer comprising the ethylenic unsaturated bonds, and also it preferably includes the energy ray polymerizable monomer.

As for the energy ray curable resin, the mixture between the polymer or the oligomer comprising the ethylenic unsaturated bonds is preferably used; and as the polymer or the oligomer comprising the ethylenic unsaturated bonds, urethane based polymer or oligomer comprising the ethylenic unsaturated double bonds is preferable.

Also, as the energy ray curable resin, for example, urethane based oligomer, silicone based oligomer and the mixture thereof or so are used. Among these, urethane based oligomer is preferable, and urethane acrylate based oligomer is particularly preferable since it is easy to regulate the viscosity and the reactivity, and the obtained base film will have high stress relieving property and expansion property.

Urethane acrylate based oligomer may be any of, for example, polyether type urethane acrylate based oligomer, polyester type urethane acrylate based oligomer, or polycarbonate type urethane acrylate based oligomer or so. However, from the point of strength, elongation and abrasion resistance of the base film suitable for the semiconductor processing step can be easily obtained; polycarbonate type urethane acrylate based oligomer is preferable.

These urethane based oligomer is obtained for example by reacting (meth)acrylate comprising hydroxyl group to terminal isocyanate urethane prepolymer which is obtained by reacting the polyol compounds such as polyether type, polyester type or polycarbonate type or so with the polyvalent isocyanate compound. Note that, (meth)acrylate refers to both acrylate and methacrylate.

As the polyol compound of polyether type, for example, polyol compounds including alkyleneoxy group such as polyethylene glycol, polypropylene glycol, polybutylene glycol, polytetramethylene glycol or so may be mentioned; and as further preferable polyether type polyol compound, polyethylene glycol, polypropylene glycol may be mentioned.

The polyol compound diol of polyester type refers to those obtained from the condensation reaction between the polybasic acid and glycols.

As the polybasic acid, generally known polybasic acids such as phthalic acid, adipic acid, phthalic anhydride, isophthalic acid, terephthalic acid, tetrahydrophthalic anhydride, methylcyclohexane-1,2-dicarboxylic acid anhydride, dimethylterephthalic acid, cis-1,2-dicarboxylic anhydride, dimethylterephtalic acid, monochlorphthalic acid, dichlorphthalic acid, trichlorphthalic acid, tetrabromophtalic acid or so may be used.

As glycols, it is not particularly limited, and for example, ethylene glycol, diethylene glycol, propylene glycol, 1,4-butane diol, 1,5-pentane diol, neopentyl glycol, 1,6-hexane diol or so may be mentioned.

In addition, as the polyol compounds of polyester type, polycaprolactone diol or so obtained by the ring-opening polymerization of said glycols and ε-caprolactone may be mentioned.

As the polyol compounds of carbonate type, for example 1,4-tetramethylenecarbonate diol, 1,5-pentamethylenecarbonate diol, 1,6-hexamethylene carbonate diol, 1,2-propylenecarbonate diol, 1,3-propylenecarbonate diol, 2,2-dimethylpropylenecarbonate diol, 1,7-heptamethylenecarbonate diol, 1,8-octamethylenecarbonate diol, and 1,9-nonanemethylenecarbnate diol, 1,4-cyclohexanecarbonate diol or so may be mentioned.

Said polyol compounds may be used alone or by mixing two or more thereof. The above mentioned polyol compounds generates terminal isocyanate urethane prepolymer by the reaction between polyvalent isocyanate compound.

As the polyvalent isocyanate compound, for example, 4,4′-dicyclohexylmethane diisocyanate, isophorone diisocyanate, 2,4-tolyene diisocyanate, 2,6-tolyene diisocyanate, 1,3-xylene diisocyanate, 1,4-xylene diisocyanate, diphenyl methane-4,4′-diisocyanate or so are used, and particularly preferably, 4,4′-dicyclohexyl methane diisocyanate, hexamethylene diisocyanate, tetramethylene diisocyanate, trimethylhexamethylene diisocyanate, norbornane diisocyanate, dicyclohexyl methane-2,4′-diisocyanate or so are used.

Next, urethane acrylate based oligomer can be obtained by reacting the above mentioned polyol compounds with terminal isocyanate urethane prepolymer obtained by the reaction between the above mentioned polyvalent isocyanate compound, and (meth)acrylate having hydroxyl group. As for (meth)acrylate having the hydroxyl group, it is not particularly limited as long as it is a compound having the hydroxyl group and (meth)aclyoyl group in one molecule. For example, hydroxyl alkyl(meth)acrylate such as 2-hydroxyethyl(meth)acrylate, 2-hydroxypropyl(meth)acrylate, 2-hydroxybutyl(meth)acrylate, 4-hydroxycyclohexyl(meth)acrylate, 5 -hydroxycyclooctyl(meth)acrylate, 2-hydroxy-3 -phenyloxypropyl(meth)acrylate, pentaerythritol tri(meth)acrylate or so; polyethylene glycol(meth)acrylate, polypropylene glycol (meth)acrylate or so can be used.

The obtained urethane acrylate based oligomer has the ethylenic unsaturated bonds in the molecule, and it polymerize cures by the energy ray irradiation, thereby it has a property to form the film.

The weight average molecular weight of urethane acrylate based oligomer preferably used in the present invention is 1000 to 50000, and more preferably 2000 to 40000. The above mentioned urethane acrylate based oligomer may be used alone or by combining two or more thereof.

However, in case of using urethane acrylate based oligomer as mentioned in the above alone, the membrane production may become difficult, thus in the present invention, preferably the energy ray curable resin is the mixture between urethane based oligomer and the energy ray polymerizable monomer. By including the energy ray polymerizable monomer, it is preferable because the viscosity can be regulated, and the membrane production becomes easy. The energy ray polymerizable monomer comprises the ethylenic unsaturated bonds in the molecule, and particularly in the present invention, acrylate based compound having relatively bulky group is preferably used.

As the specific example of the energy ray polymerizable monomer, alicyclic compounds such as isobornyl (meth)acrylate, dicyclopentenyl (meth)acrylate, dicyclopentanyl (meth)acrylate, dicyclopentenyl (meth)acrylate, cyclohexyl (meth)acrylate, adamantine (meth)acrylate, tricyclodecane acrylate or so; aromatic compounds such as phenylhydroxypropyl acrylate, benzyl acrylate, phenolethyleneoxide modified acrylate or so; heterocyclic compounds such as tetrahydrofurfuryl (meth)acrylate, morpholine acrylate, N-vinylpyrrolidone or N-vinylcaprolactam or so may be mentioned. Also, depending on the needs, polyfunctional (meth)acrylate may be used. Such energy ray polymerizable monomer may be used alone or by combining two or more thereof.

The above mentioned energy polymerizable monomer is used preferably in 5 to 900 parts by weight, more preferably 10 to 500 parts by weight, and particularly preferably 30 to 200 parts by weight with respect to 100 parts by weight of urethane acrylate based oligomer. The energy ray curable resin preferably includes urethane based oligomer and the energy ray polymerizable monomer.

Also, as the energy ray polymerizable monomer, in addition to the above mentioned, epoxy modified (meth)acrylate can be used.

As epoxy modified acrylate, bisphenol A modified epoxy acrylate, glycol modified epoxy acrylate, propylene modified epoxy acrylate, phthalic acid modified epoxy acrylate or so may be mentioned.

The energy ray curable resin generates the base film by forming the film by undergoing the polymerization and curing caused by the energy ray irradiation. By blending the photopolymerization initiator when carrying out the energy ray irradiation, the time for the polymerize curing by the energy ray irradiation and the energy ray irradiation amount can be reduced. As for such photopolymerization initiator, a photopolymerization initiator such as benzoin compound, acetophenone compound, acylphosphinoxide compound, titanocene compound, thioxanthone compound, peroxide compound or so, a photosensitizer such as amine or quinone or so may be mentioned; and specifically 1-hydroxycyclohexylphenyl ketone, 2-hydroxy-2-methyl-1-phenylpropane-1-one, benzoin, benzoin methylether, benzoin ethylether, benzoin isopropylether, benzyldiphenyl sulfide, tetramethylthiuram monosulfide, azobisisobutylonitrile, dibenzyl, diacetyl, 13-chloranthraquinone or so may be mentioned.

The used amount of the photopolymerization initiator is preferably 0.05 to 15 parts by weight, more preferably 0.1 to 10 parts by weight, and particularly preferably 0.3 to 5 parts by weight with respect to 100 parts by weight of the energy ray curable resin.

### (Ionic Liquid Comprising the Ethylenic Unsaturated Bonds)

“Ionic liquid” is also called as “normal temperature molten salt”, and it is a molten salt at room temperature (for example at 25° C.). Since the ionic liquid is in a liquid state at room temperature, it has excellent compatibility with the energy ray curable resin compared to the solid salt, thus adding, dispersing or dissolving are easy, hence the base film having stable antistatic property can be obtained.

The ionic liquid used in the present invention is not particularly limited as long as it is a salt made of cation and anion, and comprises one or more functional group including the ethylenic unsaturated bonds in the molecule.

As the functional group including the ethylenic unsaturated bonds, for example, alkenyl group comprising terminal double bond having the carbon atoms of 2 to 10 such as vinyl group or so, (meth)acryloyl group or so may be mentioned. Such functional groups may be substituted with cation and/or anion.

In case the functional group including the ethylenic unsaturated bonds is substituted with cation, as for cation, it is not particularly limited, as long as it is cation of usual ionic liquid, and for example, nitrogen containing onium cation such as ammonium cation, amidinium cation, imidazolium cation, pyridium cation or so, sulfur containing onium cation such as sulfonium cation or so, phosphorous containing onium cation such as phosphonium cation or so can be used.

As the counter anions, it is not particularly limited, as long as it is those used as the anions of usual ionic liquid. For example, Cl⁻, Br⁻, I—, AlCl₄₋, Al₂Cl₇₋, BF₄₋, PF₆₋, ClO₄₋, NO₃₋. CH₃COO⁻, CF₃COO³¹ , CH₃SO₃₋, CF₃SO₋, (FSO₂)₂N⁻, (CF₃SO₂)₂N⁻, (CF₃SO₂)₃C⁻, AsF₆₋, SbF₆₋, NbF₆₋, TaF₆₋, F(HF)ₙ₋, (CN)₂N⁻, C₄F₉SO₃₋, (C₂F₅SO₂)₂N, C₃F₇COO−⁻, (CF₃SO₂)(CF₃CO)N⁻ or so may be used. As such ionic liquid as mentioned in above, those already known or those which are commercially available ones can be used; and as for the commercially available ones, for example Quatermer series (QA-HA05, QA-KA05, QA-JA05) made by KOHJIN Film & Chemicals Co., Ltd or so may be mentioned as ammonium salt type ionic liquid, and specifically the compounds shown in the below general formulas (1) to (4) may be mentioned.

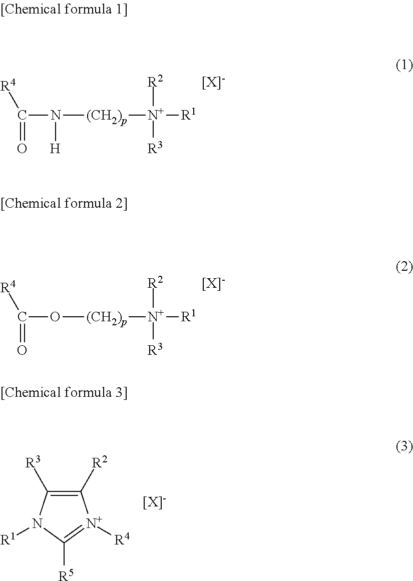

In the above formulas (1) to (3), R¹, R², R³ and R⁵ each independently shows hydrogen atom; hydroxyl group; hydrocarbon groups with or without substitution of alkyl group, aryl group, heteroaryl group, aralkyl group and heteroaralkyl group or so; and these may be same or different from each other, or it may form a ring together. R⁴ is alkenyl group comprising terminal double bond, and p is integer of 1 to 6.

Among these, from the point of excellent compatibility with the energy ray curable resin, R¹, R², R³ and R⁵ are preferably hydrogen atom, alkyl group having the carbon atoms of 1 to 10 or aryl group having the carbon atoms of 6 to 20; more preferably it is hydrogen atom or alkyl group having the carbon atoms of 1 to 10; further preferably it is hydrogen atom or alkyl group having the carbon atoms of 1 to 3; and even more preferably it is vinyl group.

Also, in the formulas (1) to (3), as the counter anions, the above mentioned counter anions can be used.

In case the functional group including the ethylenic unsaturated bonds are substituted by anions, as anions, it is not particularly limited as long as it is those used as anions of usual ionic liquids, and for example, sulfuric acid ion, carboxylic acid ion or so may be used. As the counter cations, it is not particularly limited as long as it is those used as cations of usual ionic liquids, and for example, nitrogen containing onium cation such as ammonium cation, amidinium cation, imidazolium cation, pyridium cation or so, sulfur containing onium cation such as sulfonium cation or so, phosphorous containing onium cation such as phosphonium cation or so may be used. As such ionic liquids, those already known or those which are commercially available ones can be used; and as for the commercially available ones, for example LATEMUL PD-105 made by Kao Corporation; and specifically the compound shown in the following general formula (4) may be mentioned.

[Chemical formula 4]

R⁶O—(BO)ₘ—(EO)ₙ—SO₃⁻[Y]⁺ (4)

In the formula (4), R⁶ is alkenyl group having terminal double bond; BO is butylene oxide; EO is ethylene oxide; and m and n are an integer of 1 to 12. As the counter cation, those mentioned in the above can be used.

Such ionic liquid comprising the ethylenic unsaturated bonds at the end can polymerize with the energy ray curable resin, thus the ionic liquid can be fixed in the base film. Thereby, the predetermined antistatic property can be obtained stably, and the performance of the device does not decline. Also, by using such ionic liquid, the ionic liquid does not segregate at the base film surface, or does not bleed out; thus the static friction coefficient of the base film surface can be prevented from becoming high, and the adhesive sheet having high processing aptitude during the semiconductor processing step can be obtained.

The ionic liquid used in the present invention is further preferably the compound comprising the ethylenic unsaturated bonds and also comprises polyoxyalkylene chain in the molecule. If the ionic liquid is the compound comprising polyoxyalkylene chain in the molecule, it has high compatibility with the energy ray curable resin having high polarity such as urethane oligomer or so, thus it can be easily dispersed in the base film. Thereby, the film with low static friction coefficient of the surface of the base film, and stable antistatic property can be obtained.

As for such compound comprising polyoxyalkylene chain in the molecule, it is not particularly limited as long as it becomes the ionic liquid, however for example, polyoxyethylene ammonium sulfate and polyoxyethylene phosphoric acid ester or so may be mentioned. Specifically, the compounds shown in the above general formula (4), the below shown general formulas (5) and (6) are preferably used. If it is the ionic liquid shown in the above general formula (4), the below shown general formulas (5) and (6), it does not include the halogen based anion as the anion, thus it is further preferable from the point that it can prevent the corrosion of the semiconductor.

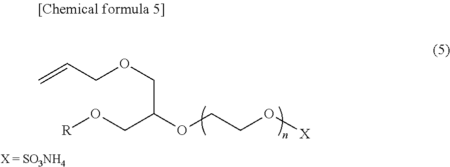

In the formula (5), R is alkyl group having the carbon atoms of 8 to 15, and n is an integer of 2 to 20. As the commercially available product of the compound shown in the above general formula (5), ADEKA REASOAP SR-10 (n=10) or ADEKA REASOAP SR-20 (n=20) or so made by ADEKA CORPORATION may be mentioned.

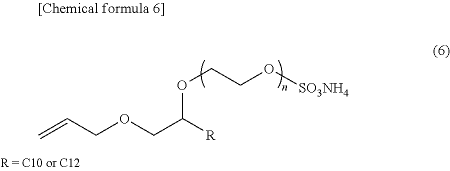

In the above formula (6), n is an integer of 1 to 15. As the commercially available product of the compound shown in the above general formula (6), AQUALON KH-05 (the mixture between the compound having R═C10 and n=5, and the compound of R═C12 and n=5), or AQUALON KH-10 (the mixture between the compound having R═C10 and n=10, and the compound of R═C12 and n=10) or so may be mentioned.

The added amount of the ionic liquid is 1 to 50 wt %, more preferably 3 to 20 wt % and further preferably 3 to 10 wt % with respect to total 100 wt % of the energy ray curable resin and the ionic liquid comprising the ethylenic unsaturated bonds. By having the blending amount of the ionic liquid within the above mentioned range, the antistatic property and the handling property suitable for the semiconductor processing step can be obtained.

That is, when the blending amount of the ionic liquid is within the above mentioned range, higher antistatic property can be provided to the base film. Also, the breaking elongation of the base film tends to be within the suitable range, and it prevents the adhesive sheet from becoming easily broken, for example when the base film is used as the base of the dicing sheet for the semiconductor processing, it prevents the dicing sheet from breaking when the dicing sheet is stretched after the dicing. Also, the compatibility between the ionic liquid and the energy ray curable resin is maintained, and the transparency of the base film tends to improve. The improvement of the transparency of the base film can be verified by the lowering of the haze of the base film.

### (The Energy Ray Curable Composition)

The energy ray curable composition includes the above mentioned energy ray curable resin, the ionic liquid and a photopolymerization initiator if needed.

The energy ray curable composition is made by regulating the component ratio so that the viscosity at 25° C. is within the range of 100 to 5,000,000 mPa·s, more preferably 300 to 2,000,000 mPa·s, and further preferably 500 to 1,000,000 mPa·s. Also, it is prepared so that the viscosity at 60° C. is within the range of 100 to 200,000 mPa·s, more preferably 300 to 100,000 mP·as. The viscosity of the energy ay curable composition tends to decline as more low molecular weight compound is included, and tends to increase as more high molecular weight compound is included, thus the viscosity can be regulated by the blending ratio of each component. If the viscosity is too low, it becomes difficult to form thick film, therefore a base film having desired thickness may not be obtained. Also, if the viscosity is too high, the coating itself may become difficult.

The energy ray curable composition does not have to include a solvent but it may be included in a small amount in order to regulate the viscosity. In case the energy ray curable composition includes the solvent, it is necessary to have a step for removing the solvent after coating the energy ray curable composition. Therefore, the solvent is used in a small amount for the viscosity regulation and it may be included in the ratio of less than 70 parts by weight with respect to 100 parts by weight of the energy ray curable composition.

Also, in the energy ray curable composition, an inorganic filler, a metal filler, an antioxidant, an organic lubricant, and a coloring agent or so may be added within the range which does not compromise the performance.

### (The Production Method of the Base Film)

As the method of the production of the film, the method called the flow casting (casting) can be preferably employed. Specifically, the base film used in the present invention is produced by forming a thin film on the processing sheet by for example casting the energy ray curable composition including the above mentioned energy ray curable resin and the above mentioned ionic liquid, then curing by irradiating the energy ray such as ultraviolet ray or electron beam or so to the film. Also, the base film may be produced by semicuring the coated film by irradiating the energy ray then further laminating the release film on the semicured coated film, and then curing by further irradiating the energy ray to form the film.

According to such production method, the stress applied to the resin during the film production is less hence it is easier to obtain isotropic film, and since the liquid material can be filtered, the fish eyes is less likely to form which is caused by the contaminant and defects. Also, the uniformity of the film thickness is high, and the accuracy of the thickness is usually within 3%. Further, the base film produced as such has larger breaking elongation. Also, as other method of producing the film, the extrusion molding using T dye or inflation method or a calendar method or so may be used for the production.

As for the energy ray, usually, ultraviolet ray and electron beam or so is used. The amount of irradiation of the energy ray differs depending on the type of the energy ray, and for example in case of the ultraviolet ray, the luminous energy of 10 to 2000 mJ/cm² or so is preferable; and if it is electron beam 10 to 1000 krad or so is preferable. The ultraviolet ray irradiation can be carried out by the high pressure mercury lamp or xenon lamp or so.

Also, the static friction coefficient of the face of the base film opposite of the face where the adhesive film is provided is preferably 1.0 or less, and 0.1 to 1.0 is more preferable. The base film having the static coefficient within said range is unlikely to adhere to the metal roll, to have blocking suppression when winding the adhesive sheet in a roll shape, the adhesion suppression between the metal roll which is attached to the device such as tape laminator and the laminator or so, and the processing malfunction caused by adhering to the semiconductor processing table; thus it is preferable as the production and processing aptitude can be obtained.

Also, the static voltage of the base film face 60 seconds after applying 10 kV voltage to the base film is preferably 2.0 kV or less, and more preferably 1.0 kV or less. If the static voltage of the base film face is 2.0 kV or less, the release charge is suppressed which is generated when releasing the adhesive sheet from the release film, or releasing the adhesive sheet from the adherend such as the semiconductor wafer or so, thus the device can be prevented from breaking by the leakage current.

Also, the tensile modulus of the base film is preferably 1 to 1000 MPa, more preferably 50 to 800 MPa, and further preferably 100 to 500 MPa. When the base film having the tensile modulus within such range is used to the base of the adhesive sheet used during the dicing step by the blade or the laser beam, it can follow the bumps on the surface of the workpiece and absorb the height difference of the bumps, hence it can maintain the workpiece without being influenced by the bumps on the surface of the workpiece, thereby the chipping or the cracking of the chip formed by cutting the workpiece can be suppressed.

The breaking elongation of the base film is preferably 80% or more, and more preferably 90% or more, and particularly preferably 100% or more. When the base film having the breaking elongation of 80% or more is used as the base for the dicing sheet for the semiconductor processing, it is unlikely to break when the dicing sheet is stretched after the dicing, hence it is preferable as the handling property of the pickup of the chip formed by cutting the workpiece can be improved.

The thickness of the base film is not particularly limited, however, from the point of working property or so, it is usually 10 to 1000 μm, preferably 30 to 500 μm, and further preferably 50 to 300 μm.

### [The Adhesive Sheet]

The adhesive sheet according to the present invention is produced by laminating the adhesive layer on at least one face of the above mentioned base film.

Note that, in case the adhesive layer is formed by the ultraviolet ray curing adhesive, and the ultraviolet ray is used as the energy ray irradiation for curing the adhesive, the base film which is transparent against the ultraviolet ray is preferable. Note that, in case of using the electron beam as the energy ray, it does not have to be transparent. Other than the above mentioned base film, the colored transparent of these, or a non-transparent film or so can be used.

Also, at the surface of the base film which is provided with the adhesive layer, in order to improve the adhesiveness between the adhesive layer, corona treatment may be carried out or a primer layer may be provided. Also, at the sheet face opposite of the adhesive layer, various films may be coated. Further, at the surface of the base film, in order to enhance the antistatic property of entire adhesive sheet, the layer blending ionic substance, conductive polymer, metal compound particle, and carbon isotope or so may be provided.

### (The Adhesive Layer)

As the adhesive layer, it is not particularly limited, and it can be formed by various known adhesives. As such adhesive, it is not particularly limited, and for example, the adhesive such as rubber based, acrylic based, silicone based, polyvinylether based or so can be used. Also, in case the adhesive sheet is used for the processing of the semiconductor wafer, the energy ray curing adhesive having releasable property by being cured by energy ray irradiation, and the adhesive of heat foaming type, water swelling type or so can be used; and preferably it is energy ray curing adhesive. These adhesives can be used alone or by combining two or more thereof.

As the energy ray curing adhesive, it can be formed from various energy ray curing adhesive which cures by irradiating the energy ray such as conventionally known gamma rays, electron beams, ultraviolet rays and visible lights or so; however it is preferable to particularly use the ultraviolet ray curing adhesive.

As specific examples of such energy ray curing adhesive, for example, it is disclosed in Japanese Patent Application Laid Open No.S60-196956 and Japanese Patent Application Laid Open No.S60-223139; however further specifically, for example the adhesive mixing the polyfunctional energy ray curing resin with acrylic based adhesive may be mentioned. As for the polyfunctional energy ray curing resin, the low molecular weight compound comprising plurality of energy ray polymerizable functional group, urethane acrylate oligomer or so may be mentioned. Also, the adhesive including the acrylic based polymer comprising the energy ray polymerizable functional group at the side chain can be used as well. As such energy ray polymerizable functional group, (meth)acryloyl group is preferable.

The glass transition temperature (Tg) of the adhesive layer is preferably −50 to 30° C., and more preferably −25 to 30° C. Here, Tg of the adhesive layer is the temperature which shows the maximum value of loss tangent (tans) at the range of −50 to 50° C. in the dynamic elasticity measurement at the frequency of 1 Hz of the sample stacked with the adhesive layer. Note that, in case the adhesive layer is the energy ray curing adhesive, it refers to the glass transition temperature before curing the adhesive layer by the energy ray irradiation.

In the adhesive layer, plastisizer tackifier or so may be blended. Also, by blending ionic substances, conductive polymers, metal compound particles, and carbon isotopes or so, the antistatic property can be provided, thereby the antistatic property of the entire adhesive sheet can be further enhanced.

The thickness of the adhesive layer is not particularly limited, however preferably it is 1 to 100 μm, more preferably 3 to 80 μm, and particularly preferably 5 to 50 μm.

Note that, at the adhesive layer, the release sheet for protecting the adhesive layer may be laminated before use. As the release sheet, it is not particularly limited, and for example, the base for the release sheet treated with the release agent can be used. As the base for the release sheet, for example the film made of the resin such as polyethyleneterephthalate, polybutyleneterephthalate, polypropylene, polyethylene or so, or the foaming film thereof, or papers such as glassine paper, coat paper, and laminate paper or so may be mentioned. As the release agent, for example, the release agent of silicone based, fluorine based, long chain alkyl group containing carbamate or so may be mentioned.

As the method of providing the adhesive layer to the surface of the base film, the adhesive layer which is formed by coating at a predetermined film thickness on the release sheet may be transferred to the surface of the base film, or it may be formed by directly coating the adhesive layer on the surface of the base film.

### (The Production of the Adhesive Sheet)

The adhesive sheet of the present invention can be produced by coating and drying the adhesive in appropriate thickness which forms the adhesive layer using the known coating device, then by crosslinking the reactive functional group and the crosslinkable group in each component by applying the heat at the temperature of 80 to 150° C. As the coating device, a roll coater, a knife coater, a roll knife coater, a fountain die coater, a slot dye coater, a reverse coater or so may be mentioned. On the adhesive layer, preferably the release sheet is adhered to protect the adhesive face. Also, it may be produced by providing the adhesive layer on the release sheet and further transferring on the base film.

The adhesive sheet according to the present invention can be any shape such as tape shape, label shape or so. Also, it may be a shape (precut shape) wherein the adhesive sheet is cut out in advance in a shape of the adherend. The adhesive sheet having the precut shape can be obtained by so called half-cut method wherein among the adhesive sheet laminated with the release sheet, only the adhesive sheet is completely punched out in an adherend shape, and the release sheet is not completely cut. Here, in order to completely cut the adhesive sheet, it is preferable to make some degree of cut to the release sheet. However, if the release sheet is cut too much, the strength will decline, and the workability will be compromised. Therefore, the depth of the cut to the release sheet is 30% or less, and more preferably 20% or less of the entire thickness of the release sheet.

### [The Processing Method of the Semiconductor Wafer]

The adhesive sheet of the present invention can be used for the processing of the semiconductor wafer as shown in below.

### (The Backside Grinding Method of the Semiconductor Wafer)

The adhesive sheet of the present invention can be used as the surface protection sheet for protecting the circuit face during the backside grinding of the semiconductor wafer. When using as the surface protection sheet, during the backside grinding of the semiconductor wafer, the adhesive sheet is adhered to the circuit face of the semiconductor wafer formed with the circuit on the surface, and protects the circuit face, then the backside of the wafer is ground, thereby the wafer having a predetermined thickness can be obtained.

The semiconductor wafer may be a silicon wafer, or it may be a compound semiconductor wafer such as gallium-arsenic or so. The formation of the circuit to the wafer surface can be carried out by various methods including the method conventionally used such as an etching method, a liftoff method or so. During the circuit forming step of the semiconductor wafer, a predetermined circuit can be formed. The thickness before the grinding of such wafer is not particularly limited, however usually it is 500 to 1000 μm or so. Also, the surface shape of the semiconductor wafer is not particularly limited, however the adhesive sheet of the present invention is preferably used for the surface protection of particularly of the wafer formed with the bumps on the circuit surface.

The backside grinding is carried out by the known method for example using the grinder and the suction table for fixing the wafer while the adhesive layer is adhered. After the backside grinding step, the treatment for removing the fractured layer caused by the grinding may be carried out. The thickness of the semiconductor wafer after the backside grinding is not particularly limited, however preferably it is 10 to 300 μm, and particularly preferably 25 to 200 μm so.

After the backside grinding step, the adhesive sheet is released from the circuit face. According to the adhesive sheet of the present invention, the base film made by curing a membrane comprising the energy ray curable composition including the above mentioned energy ray curable resin and the above mentioned ionic liquid is used, thus the adhesive sheet barely have a charge, and it reduces the risk of breaking the circuit of the device by the leakage current caused by the adhesive sheet having the charge due to the static generated during the releasing of the adhesive sheet from the circuit face. Further, the wafer can be securely maintained during the backside grinding of the wafer, and also it can prevent the infiltration of the grinding water to the circuit face.

### (The Dicing Method of the Semiconductor Wafer)

The adhesive sheet of the present invention can be used as the dicing sheet. When using as the dicing sheet, the adhesive sheet of the present invention is adhered to the wafer, and the wafer is cut. Particularly, it is suitable in case of adhering the adhesive sheet of the present invention to the circuit face of the wafer and then cutting the wafer while protecting the circuit face by the adhesive sheet. The adhering of the dicing sheet is generally carried out by the device called mounter, but it is not limited thereto.

The means for cutting the semiconductor wafer is not particularly limited. As an example, the method of fixing the surrounding part of the dicing tape by the ring frame during the dicing of the wafer, then forming a chip of the wafer by known means such as by using the rotating circular blade such as the dicing blade or so may be mentioned. Also, the dicing method using the laser beam may be used.

By using the adhesive sheet of the present invention, the chips formed by cutting the workpiece are spaced apart; hence the risk of breaking the circuit of the device by the static electricity generated during the pickup of the chip can be reduced.

### (The Pre-Dicing Method of the Semiconductor Wafer)

Furthermore, the adhesive sheet of the present invention is preferably used for forming the chip from the wafer with high bumps using the so called pre-dicing method. Specifically, it is preferably used for the production method of the semiconductor chip including steps of
forming a groove having a depth of cut shallower than a wafer thickness from a semiconductor wafer surface formed with a circuit with a bump,
adhering the adhesive sheet to said circuit formed face as the surface protection sheet,
thinning the wafer thickness by carrying out a backside grinding of said semiconductor wafer, then
dividing into each chip.

By using the adhesive sheet of the present invention, the chips are spaced apart; hence the risk of breaking the circuit of the device by the static electricity generated during the pickup of the chip can be reduced.

Then, the pickup of the chip is carried out in a predetermined method. Also, alternatively, before the pickup of the chip, the chip which is aligned in a wafer shape may be transferred to other adhesive sheet, and then the pickup of the chip may be carried out.

In case the adhesive sheet is used as the dicing-dye bonding sheet, the bonding layer for bonding the dye may be provided on the adhesive layer, or the adhesive layer may also have the dye bonding function as well. Hereinafter, the bonding layer and the adhesive layer comprising the dye bonding function may be simply referred as “the bonding resin layer”.

When using the adhesive sheet of the present invention as the dicing-dye bonding sheet, the bonding resin layer holds the semiconductor wafer during the dicing step, and when dicing, it is cut with the wafer, then the bonding resin layer having the same shape will be formed at the chip being cut. Then, if the pickup of chip is carried out after completing the dicing, the bonding resin layer is released from the adhesive sheet with the chip, then the chip with the bonding resin layer is placed on the base to carry out the heat applying, thereby the chip and the adherend such as the base or other chip are bonded via the bonding resin layer.

The bonding resin layer includes for example, the above mentioned acrylic based adhesive, heat curable resin such as epoxy bonding agent or so, and also if necessary, the energy ray curing compound and curing auxiliary agent or so.

In case the adhesive sheet is the sheet for forming the protective film, the resin layer having the bonding property (the protective film forming layer) for forming the protective film may be provided on the adhesive layer, or the adhesive layer may comprise the protective film function as well. Hereinafter, the protective film forming layer and the adhesive layer comprising the protective film function may be simply called as “the protective film forming layer”.

When using as the sheet for forming the protective film, the semiconductor wafer is adhered on the protective film forming layer, and the protective film forming layer is cured to form the protective film. Then, the semiconductor wafer and the protective film are diced, thereby the chip comprising the protective film is obtained. The protective film forming layer includes the above mentioned acrylic based adhesive, heat curable resin such as epoxy bonding agent or so, also if necessary, the energy ray curing compound and curing auxiliary agent or so, and the filler or so may be included as well.

### EXAMPLES

Hereinafter the present invention will be described based on the examples; however the present invention is not limited thereto. Note that, the evaluations of each physical properties were carried out as describe in the following.

### <The Breaking Elongation and the Tensile Modulus>

The breaking elongation was measured in accordance with JIS K7161:1994 and JIS K7127:1999, and when the test piece did not have the yield point, the strain at the break was determined as the breaking elongation, and when it did have the yield point, then the nominal tensile strain at break was determined as the breaking elongation. Here, the base film used in the examples and the comparative examples was cut into a size of width of 15 mm and the length of 140 mm, and the cover plate (label) for tensile test piece was adhered to the both ends of 20 mm, thereby the measurement sample was formed. By using this measurement sample, the tensile modulus was measured by universal testing machine (Autograph AG-1S SOON made by Shimadzu Corporation) at the speed of 200 mm/min.

### <The Static Friction Coefficient>

The static friction coefficient was measured under the following condition in regards with the base film face of the side contacting the processing sheet during the base film production.

In accordance with JIS K7125:1999, the adherend was SUS#600, and the static friction coefficient was measured using measurement apparatus universal testing machine (Autograph AG-1S SOON made by Shimadzu Corporation) at the load of 200 g and the contact time of 1 second.

### <The Static Voltage>

The static voltage was measured under the following condition, regarding the base film face of the side contacting to the processing sheet when forming the base film. Under the atmosphere of 23° C. and 50%RH, the adhesive sheet having the size of 40 mm×40 mm was placed on the static electricity attenuation measuring device (product name “STATIC HONESTMER” made by SHISHIDO ELECTROSTATIC LTD) facing the base film side up; then it was rotated at 1300 rpm, and the voltage of 10 kV was applied to the base film face. Then, the static voltage of the base film after 60 seconds after the application of the voltage was measured, thereby the static voltage was determined.

### <The Haze>

The haze of the base film was measured using the haze meter NDH 5000 made by NIPPON DENSHOKU INDUSTRIES Co., LTD.

Also, as for the energy ray curable resin, the ionic liquid comprising the ethylenic unsaturated bonds, and the adhesive composition constituting the bonding resin layer (the adhesive layer), the followings were used.

### (The Energy Ray Curable Resin)

A: The energy ray curable resin (Beamset 541 having viscosity 6,000 mPa·s (25° C.) made by ARAKAWA CHEMICAL INDUSTRIES, LTD) including polycarbonate type urethane based oligomer, energy ray polymerizable monomer and the photopolymerization initiator
B: The energy ray curable resin (Beamset 542 having viscosity 5,300 mPa·s (25° C.) made by ARAKAWA CHEMICAL INDUSTRIES, LTD) including polycarbonate type urethane based oligomer, energy ray polymerizable monomer and the photopolymerization initiator
C: The energy ray curable resin (Beamset 543 having viscosity 5,100 mPa·s (25° C.) made by ARAKAWA CHEMICAL INDUSTRIES, LTD) including polycarbonate type urethane based oligomer, energy ray polymerizable monomer and the photopolymerization initiator

### (The Ionic Liquid)

a: QM-HAO5 (annmonium salt type ionic liquid comprising the ethylenic unsaturated bonds made by KOHJIN Film & Chemicals Co., Ltd)
b: QM-JA05 (annmonium salt type ionic liquid comprising the ethylenic unsaturated bonds made by KOHJIN Film & Chemicals Co., Ltd)
c: QM-KA05 (annmonium salt type ionic liquid comprising the ethylenic unsaturated bonds made by KOHJIN Film & Chemicals Co., Ltd)
d: LAMTEL PD-105 (ionic liquid comprising the ethylenic unsaturated bonds and polyalkylene chain in the molecule made by Kao Corporation)
e: ADEKA REASOAP SR-10 (ionic liquid comprising the ethylenic unsaturated bonds and polyalkylene chain in the molecule made by ADEKA Corporation)
f: ADEKA REASOAP SR-20 (ionic liquid comprising the ethylenic unsaturated bonds and polyalkylene chain in the molecule made by ADEKA Corporation)
g: AQUALON KH-05 (ionic liquid comprising the ethylenic unsaturated bonds and polyalkylene chain in the molecule made by DKS Co.,Ltd)
h: AQUALON KH-10 (ionic liquid comprising the ethylenic unsaturated bonds and polyalkylene chain in the molecule made by DKS Co.,Ltd)
i: IL-P14 (pyrimidinium based ionic liquid made by KOEI CHEMICAL COMPANY LIMITED)

### (The Adhesive Composition)

The adhesive composition made by mixing 3 parts by weight of polyvalent isocyanate compound (CORONATE L (made by NIPPON POLYURETHANE INDUSTRY CO.,LTD)) with 30 wt % toluene solution of copolymer (the weight average molecular weight MW: 700,000) comprising 84 parts by weight of butyl acrylate, 10 parts by weight of methyl methacrylate, 1 part by weight of acrylic acid, 5 parts by weight of 2-hydroxyethylacrylate.

### Example 1

### (The Energy Ray Curable Composition)

The energy ray curable resin and the ionic liquid comprising the ethylenic unsaturated bonds shown in Table 1 were mixed in a predetermined ratio, thereby the energy ray curable composition was obtained. The added amount of the ionic liquid comprising the ethylenic unsaturated bonds shown in the table shows the ratio with respect to total 100 wt % of the energy ray curable resin and the ionic liquid comprising the ethylenic unsaturated bonds.

### (The Production of the Base Film)

The obtained energy ray curable composition was coated on PET film (made by TORAY INDUSTRIES, INC, Lumirror T60, PET 50 T-60 TORAY, 50 μm product) which is the processing sheet by fountain die method at 25° C. so that the thickness becomes 100 μm, thereby the film was formed.

By using belt conveyor type ultraviolet ray irradiation device (product name: ECS-401GX) made by EYE GRAPHICS CO.,LTD as the ultraviolet ray irradiation device, and using the high pressure mercury lamp (high pressure mercury lamp made by EYE GRAPHICS CO.,LTD, the product name: H04-L41) under the device condition of the ultraviolet ray lamp height 150 mm, the ultraviolet ray lamp output 3 kw (converted output 120 mW/cm), the illumination of the light wavelength of 365 nm is 271 mW/cm², the luminous energy of 177 mJ/cm² (the ultraviolet photometer: UV-351 made by ORC MANUFACTURING CO.,LTD); thereby the ultraviolet ray irradiation was carried out.

Immediately after the ultraviolet irradiation, the release film (SP-PET3801 made by Lintec Corporation) was laminated on the coated film. Note that, the laminate was carried out so that the release treated face of the release film is in contact with the coated film of the energy ray curable composition.

Next, using the same ultraviolet ray irradiation device, the second ultra violet ray irradiation was carried out from the release film side being laminated at condition of the ultraviolet ray lamp height 150 mm, the illumination of the light wavelength of 365 nm is 271 mW/cm², the luminous energy of 600 mJ/cm² (the ultraviolet photometer: UV-351 made by ORC MANUFACTURING CO.,LTD); and the total luminous energy of ultraviolet ray applied to the coated film was 1377 mJ/cm² there by the coated film was crosslinked and cured.

Next, the processing sheet and the release film were released form the cured film, thereby the base film having the thickness of 100μm was obtained.

### (The Production of the Adhesive Sheet)

Then, to the face where the release film of the base film is removed, the adhesive composition was coated, and the adhesive layer having the thickness of 10 μm was formed by drying. Thereby, the adhesive sheet formed with the adhesive layer on the base film was obtained.

For the obtained base film, the breaking elongation, the tensile modulus and haze were measured; and for the base film face of the side in contact with the processing sheet during the production of the base film, the static friction coefficient, and the static voltage were measured. The results are shown in Table 1.

### Examples 2 to 26 and Comparative Examples 1 to 4

The same procedures were carried out as the example 1 except that the energy ray curable resin and the ionic liquid shown in Table 1 were mixed in a predetermined ratio to obtain the energy ray curable composition. Note that, in the comparative examples 1, 3 and 4, the base film was obtained by forming a film by curing the energy ray curable resins A to C without using the ionic liquid comprising the ethylenic unsaturated bonds. Also, in the comparative example 2, the procedure was carried out as the example 1 except for using the energy ray curable composition obtained by mixing the energy ray curable resin and pyridimidinium ionic liquid as the ionic liquid without the ethylenic unsaturated bonds. The results are shown in Table 1.

According to Table 1, the base film of the examples 1 to 26 has excellent balance of each evaluation, and particularly the static friction coefficient was low as 1.0 or less and the static voltage was confirmed low. Further, the adhesive sheet having high processing aptitude for the antistatic prevention property and the semiconductor processing was obtained.

On the other hand, the base film of the comparative examples 1, 3 and 4 which does not include the ionic liquid had high static voltage and the static voltage prevention property were bad. Also, the base film of the comparative example 2 using the ionic liquid without the ethylenic unsaturated bonds did have the antistatic property, however the static friction coefficient was higher than 1.0, and there is a risk that the processing aptitude during the semiconductor processing may be compromised.

TABLE 1

| | | | | Ionic liquid | | | | | | | | | | | | | |
|---|---|---|---|---|---|---|---|---|---|---|---|---|---|---|---|---|---|
| | | | | | | | | | | | | Ionic liquid without | | | Static | | |
| | Energy ray | | | Ionic liquid comprising | | | | | | | | ethylenic | Tensile | | friction | Static | |
| | curable resin | | | ethylenic unsaturated bonds | | | | | | | | unsaturated bonds | modulus | Breaking | coefficient | voltage | |
| | A | B | C | a | b | c | d | e | f | g | h | i | MPa | elongation % | Ave. | kV | Haze |
| Comparative | 100 | | | | | | | | | | | | 531 | 90 | 1.2 | 2.15 | 6.77 |
| example 1 | | | | | | | | | | | | | | | | | |
| Comparative | 99 | | | | | | | | | | | 1 | 453 | 103 | 1.5 | 2.01 | 6.34 |
| example 2 | | | | | | | | | | | | | | | | | |
| Example 1 | 90 | | | 10 | | | | | | | | | 701 | 80 | 0.8 | 1.87 | 56.20 |
| Example 2 | 80 | | | 20 | | | | | | | | | 609 | 70 | 0.7 | 1.90 | 66.75 |
| Example 3 | 50 | | | 50 | | | | | | | | | 582 | 68 | 0.9 | 0.65 | 74.12 |
| Example 4 | 90 | | | | 10 | | | | | | | | 653 | 95 | 0.9 | 1.58 | 2.91 |
| Example 5 | 80 | | | | 20 | | | | | | | | 645 | 96 | 0.7 | 1.65 | 3.01 |
| Example 6 | 50 | | | | 50 | | | | | | | | 649 | 109 | 0.7 | 1.25 | 2.77 |
| Example 7 | 90 | | | | | 10 | | | | | | | 858 | 48 | 0.6 | 1.84 | 2.01 |
| Example 8 | 80 | | | | | 20 | | | | | | | 726 | 80 | 0.7 | 1.70 | 2.03 |
| Example 9 | 50 | | | | | 50 | | | | | | | 830 | 28 | 0.7 | 0.90 | 2.09 |
| Example 10 | 98 | | | | | | 2 | | | | | | 419 | 83 | 0.5 | 0.98 | 2.37 |
| Example 11 | 96 | | | | | | 4 | | | | | | 340 | 104 | 0.4 | 0.80 | 2.52 |
| Example 12 | 95 | | | | | | 5 | | | | | | 565 | 86 | 0.6 | 0.55 | 9.82 |
| Example 13 | 90 | | | | | | 10 | | | | | | 463 | 100 | 0.6 | 0.50 | 12.70 |
| Example 14 | 90 | | | | | 5 | 5 | | | | | | 487 | 82 | 0.6 | 0.74 | 8.21 |
| Comparative | | 100 | | | | | | | | | | | 739 | 93 | 0.4 | 2.10 | 1.78 |
| example 3 | | | | | | | | | | | | | | | | | |
| Example 15 | | 98 | | | | | 2 | | | | | | 537 | 110 | 0.3 | 1.43 | 1.99 |
| Example 16 | | 96 | | | | | 4 | | | | | | 435 | 113 | 0.4 | 0.75 | 5.17 |
| Example 17 | | 94 | | | | | 6 | | | | | | 356 | 105 | 0.4 | 0.64 | 8.74 |
| Example 18 | | 92 | | | | | 8 | | | | | | 308 | 127 | 0.3 | 0.59 | 14.34 |
| Comparative | | | 100 | | | | | | | | | | 436 | 120 | 1.2 | 2.08 | 1.54 |
| example 4 | | | | | | | | | | | | | | | | | |
| Example 19 | | | 98 | | | | 2 | | | | | | 390 | 111 | 0.5 | 1.78 | 1.61 |
| Example 20 | | | 96 | | | | 4 | | | | | | 262 | 101 | 0.5 | 0.70 | 3.02 |
| Example 21 | | | 94 | | | | 6 | | | | | | 199 | 114 | 0.6 | 0.57 | 5.12 |
| Example 22 | | | 92 | | | | 8 | | | | | | 152 | 114 | 0.7 | 0.48 | 6.40 |
| Example 23 | | | 95 | | | | | 5 | | | | | 258 | 101 | 0.8 | 0.35 | 8.96 |
| Example 24 | | | 95 | | | | | | 5 | | | | 280 | 93 | 0.8 | 0.48 | 13.26 |
| Example 25 | | | 95 | | | | | | | 5 | | | 280 | 93 | 0.8 | 0.33 | 28.49 |
| Example 26 | | | 95 | | | | | | | | 5 | | 263 | 99 | 0.7 | 0.46 | 13.89 |

### REFERENCES OF NUMERICAL

1: Adhesive sheet
2: Base film
3: Adhesive layer

1. An adhesive sheet comprising a base film and an adhesive layer provided on said base film, wherein said base film is made by curing a membrane comprising an energy ray curable composition including an energy ray curable resin and an ionic liquid having ethylenic unsaturated bonds.

2. The adhesive sheet as set forth in claim 1, wherein said energy ray curable resin comprises a polymer or an oligomer having the ethylenic unsaturated bonds.

3. The adhesive sheet as set forth in claim 1, wherein said energy ray curable resin includes an energy ray polymerizable monomer.

4. The adhesive sheet as set forth in claim 1, wherein said ionic liquid is a compound comprising polyoxyalkylene chain.

5. The adhesive sheet as set forth in claim 1, wherein said adhesive layer is an energy ray curing adhesive layer.

6. The adhesive sheet as set forth in claim 2, wherein said polymer or oligomer comprising said ethylenic unsaturated bonds is an urethane based polymer or oligomer comprising the ethylenic unsaturated bonds.

7. The adhesive sheet as set forth in claim 1, wherein a face of said base film opposite to a face where the adhesive layer is provided has a static friction coefficient against a stainless board of 1.0 or less.

8. The adhesive sheet as set forth in claim 1, wherein a tensile modulus of said base film is 50 to 800 MPa.

9. The adhesive sheet as set forth in claim 1, wherein a breaking elongation of said base film is 80% or more.

10. The adhesive sheet as set forth in claim 1, wherein said adhesive layer is adhered to a circuit face for protecting said circuit face of a semiconductor wafer during a grinding step of a backside of the semiconductor wafer.

11. The adhesive sheet as set forth in claim 1, wherein said adhesive layer is adhered to a semiconductor wafer during a dicing step of the semiconductor wafer.

12. An adhesive sheet, comprising:
a base film; and
an adhesive layer provided on said base film,
wherein said base film comprises a cured membrane comprising an energy ray curable composition including an energy ray curable resin and an ionic liquid having ethylenic unsaturated bonds.
